(19) United States
(12) Patent Application Publication
(10) Pub. No.: US 2018/0269122 A1
(43) Pub. Date: Sep. 20, 2018

(54) PRINTED SUBSTRATE AND ELECTRONIC DEVICE

(71) Applicant: DENSO CORPORATION, Kariya-city (JP)

(72) Inventors: Yoshiki KATO, Kariya-city (JP); Yasuhiro ISHIMOTO, Kariya-city (JP)

(21) Appl. No.: 15/907,883

(22) Filed: Feb. 28, 2018

(30) Foreign Application Priority Data
Mar. 14, 2017 (JP) 2017-48750

(51) Int. Cl. H01L 23/16; H01L 23/31

(52) U.S. Cl. CPC H01L 23/16; H01L 23/3178

(57) ABSTRACT

A printed substrate having a first surface to which an electronic component is to be fixed through an underfill material includes a groove that is recessed from the first surface. The first surface includes a pair of lands that is to be electrically connected to the electronic component. The groove extends in a first direction in which the pair of lands extends and is located in a facing region of the first surface in which the first surface is to face the electronic component. An electronic device includes the printed substrate, the electronic component fixed to the first surface and the underfill material disposed between the first surface and the electronic component.

### CROSS REFERENCE TO RELATED APPLICATION

This application is based on Japanese Patent Application No. 2017-48750 filed on Mar. 14, 2017, the disclosure of which is incorporated herein by reference.

### TECHNICAL FIELD

The present disclosure relates to a printed substrate to which an underfill material is to be applied, and an electronic device.

### BACKGROUND

An electronic device including a printed substrate and an electronic component mounted on the printed substrate has been known. For example, the electronic component is electrically connected to and fixed to a land formed in a surface of the printed substrate through a conductive adhesive such as a solder. Other than the conductive adhesive, an underfill material has been known as a material to fix the electronic component to the printed substrate. The underfill material is provided to a facing region where the electronic component and the printed substrate face each other, and thereby to connect and fix the electronic component and the printed substrate. As such, reliability of the electronic component for vibration and impact is improved.

The underfill material fixing the electronic component and the printed substrate is provided by inserting a liquid resin that includes an epoxy resin as a main constituent into the facing region between the electronic component and the printed substrate, and then hardening the liquid resin by heat. Generally, the underfill material is inserted from an edge of the electronic component after the electronic component is fixed. In this case, the liquid resin spreads before securing a contact area required for fixing the electrical component, and the liquid resin spreads to a portion where the underfill material is not required.

Since the underfill material is expensive compared to general materials of the printed substrate, it is preferable to reduce an application range of the underfill material as far as possible. JP 2009-43765 A discloses a structure including a dam so as to limit an application range of an underfill material by restricting the underfill material from spreading.

### SUMMARY

However, in JP 2009-43765 A, the dam is disposed at a periphery of the electronic component and an application range immediately below the electronic component is not controlled. In other words, an application quantity of the underfill material is not sufficiently reduced because the underfill material is applied to an entire region surrounded by the dam and including the region immediately below the electronic component.

It is an object of the present disclosure to provide a printed substrate and an electronic device capable of reducing an application quantity of an underfill material while maintaining reliability for vibration and impact.

According to a first aspect of the present disclosure, a printed substrate, having a first surface to which an electronic component is to be fixed through an underfill material, includes a groove that is recessed from the first surface. The first surface includes a pair of lands that is to be electrically connected to the electronic component. The groove extends in a first direction in which the pair of lands extends. The groove is located in a facing region of the first surface in which the first surface is to face the electronic component.

According to the first aspect of the present disclosure, when the underfill material is applied to the printed substrate to fix the electronic component and the printed substrate, a main portion of the electronic component is fixed to the printed substrate before the underfill material unnecessarily spreads. As a result, the application quantity of the underfill material is reduced.

According to a second aspect of the present disclosure, an electronic device includes the printed substrate according to the first aspect of the present disclosure, the electronic component fixed to the first surface, and the underfill material disposed between the first surface and the electronic component. According to the second aspect of the present disclosure, the application quantity of the underfill material is reduced.

According to a third aspect of the present disclosure, a printed substrate, having a first surface to which an electronic component is to be fixed through an underfill material, includes a base and a stacked layer stacked above the base. The stacked layer provides the first surface and includes a land that is to be electrically connected to the electrical component. The stacked layer includes a groove that is recessed from the first surface in a facing region in which the first surface is to face the electronic component. The groove extends in a first direction in which the land extends.

### BRIEF DESCRIPTION OF THE DRAWINGS

The above and other objects, features and advantages of the present disclosure will become more apparent from the following detailed description made with reference to the accompanying drawings in which:

FIG. 1A is a cross-sectional view taken along a line IA-IA of FIG. 1B;

FIG. 1B is a top view showing a schematic structure of an electronic device according to a first embodiment;

FIG. 2 is a top view showing a schematic structure of an electronic device according to a second embodiment;

FIG. 3 is a top view showing a schematic structure of an electronic device according to a third embodiment;

FIG. 4 is a top view showing a schematic structure of an electronic device according to other embodiments;

FIG. 5 is a top view showing a schematic structure of an electronic device according to other embodiments; and

FIG. 6 is a top view showing a schematic structure of an electronic device according to other embodiments.

### DETAILED DESCRIPTION

Hereinafter, embodiments of the present disclosure will be described with reference to the drawings. In the following embodiments, parts corresponding to parts described in the previous embodiments are designated by the same symbols and descriptions thereof will not be repeated. When a part of a configuration is described in the following embodiments, the other part of the configuration may refer to the previous embodiments. The present disclosure is not limited to combinations of parts of the embodiments clearly described in the following embodiments. Although not clearly described in the following embodiments, parts of the embodiments may be combined without generating any difficulties.

### First Embodiment

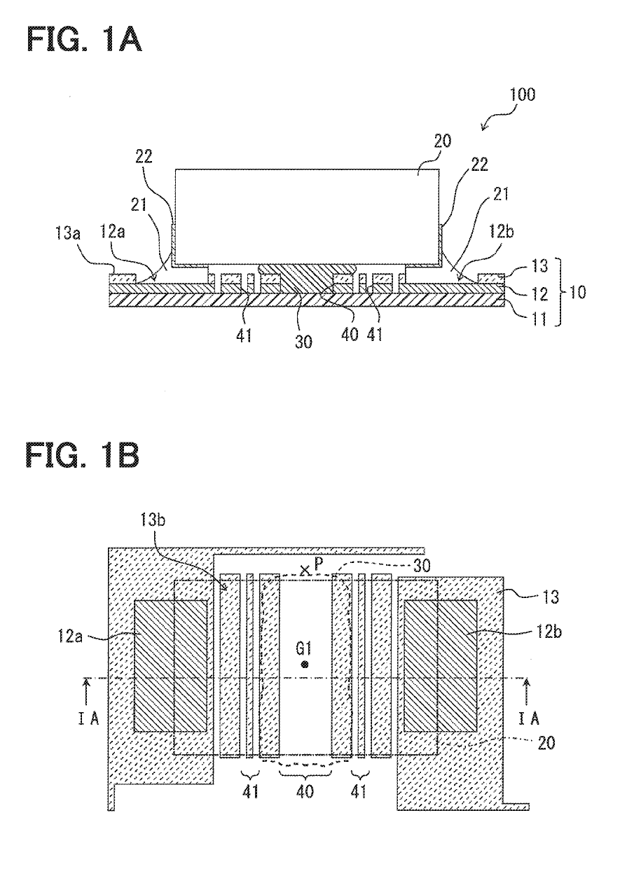

First, schematic structures of a printed substrate and an electronic device will be described with reference to FIG. 1A and FIG. 1B. Although FIG. 1B is a top view, several parts are hatched for simplifying the explanations.

As shown in FIG. 1A and FIG. 1B, an electronic device 100 includes a printed substrate 10, an electronic component 20 and an underfill material 30. The electronic component 20 is mounted on the printed substrate 10 and the electronic component 20 is further fixed to the printed substrate 10 by the underfill material 30. As such, compared to a structure without the underfill material 30, reliability for vibration and impact is improved.

The printed substrate 10 includes a base 11, a copper foil 12 and a resist 13 stacked. In FIG. 1B, the copper foil 12 and the resist 13 are illustrated. The copper foil 12 and the resist 13 are included in a stacked layer stacked above the base 11.

The base 11 is a flat plate made of resin. In FIG. 1A and FIG. 1B, an example is described in which the copper foil 12 is stacked on the base 11. However, a multi-layer substrate including multiple layers below the base 11 may be employed.

The copper foil 12 is stacked above the base 11 while being patterned. A part of the copper foil 12 where the resist 13 is not formed is exposed. The exposed part of the copper foil 12 corresponds to lands 12a and 12b. The lands 12a and 12b are electrically connected to a lead 22 of the electronic component 20 through a solder 21. The copper foil 12 is to be energized so that a predetermined potential is applied to the electronic component 20. Also, the copper foil 12 dissipates a heat transferred from the electronic component 20.

The resist 13 is a solder resist that restricts spread of the solder 21. Also, the resist 13 insulates the copper foil 12 from exterior and protects the copper foil 12 from dust. The resist 13 is applied on the copper foil 12. The resist 13 is not applied to a part of the copper foil 12 and exposes the part of the copper foil 12 to provide the lands 12a and 12b. Each of the lands 12a and 12b has a rectangular shape extending in one direction. The lands 12a and 12b provide a pair of connection terminal. Hereinafter, the direction in which the lands 12a and 12b extend may be referred to as an extension direction or a first direction.

The resist 13 has a front surface referred to as a first main surface 13a. The electronic component 20 is mounted to face the first main surface 13a of the resist 13 and is electrically connected to the lands 12a and 12b exposed from the resist 13. The electronic component 20 bridges between the pair of lands 12a and 12b. The electronic component 20 has a bottom surface facing the printed substrate 10. A region of the first main surface 13a located between the pair of lands 12a and 12b and facing the electronic component 20 is referred to as a facing surface 13b. The facing surface 13b may be referred to as a facing region 13b. For example, the electronic component 20 includes a coil, a capacitor or a resistor.

As shown in FIG. 1A and FIG. 1B, the facing surface 13b has a first groove 40 and second grooves 41 where the base 11 is exposed. In the first groove 40 and the second grooves 41, the copper foil 12 and the resist 13 are not formed above the base 11. As such, the first groove 40 and the second grooves 41 are recessed from the first main surface 13a. In other words, the printed substrate 10 has protrusions provided by the copper foil 12 and the resist 13 on a surface of the base 11 facing the electronic component 20. Accordingly, the portions where the base 11 is exposed are recessed from the first main surface 13a and provide the recesses corresponding to the first groove 40 and the second grooves 41.

The first groove 40 has a rectangular shape and a longitudinal direction of the first groove 40 corresponds to a longitudinal direction of the lands 12a and 12b (i.e., the extension direction of the lands 12a and 12b). In the present embodiment, the first groove 40 has the same width in an arrangement direction in which the lands 12a and 12b are arranged. The arrangement direction may be referred to as a second direction orthogonal to the first direction. When the first groove 40 is viewed in a direction normal to the first main surface 13a (i.e., in a front view of the first main surface 13a), the first groove 40 is positioned to overlap with an area gravity point G1 of the electronic component 20. Additionally, in the present embodiment, the first groove 40 is positioned at substantial center between the lands 12a and 12b.

In FIG. 1A, a center portion of an upper edge of the electronic component 20 is referred to as an application point P of the underfill material 30. The first groove 40 reaches a bottom edge of the electronic component 20. The bottom edge of the electronic component 20 is located at a downstream side in a spread direction in which the underfill material 30 spreads. That is, the first groove 40 extends to reach a position located immediately below a downstream edge of the electronic component 20 in the spread direction of the underfill material 30.

In other words, the first groove 40 has a first end and a second end facing in the longitudinal direction (i.e., the first direction). The first end of the groove is to be applied with the underfill material 30 and allow the underfill material 30 to spread toward the second end. The first groove 40 extends so that the second end reaches the position located immediately below the downstream edge of the electronic component 20.

The second grooves 41 are formed in the facing surface 13b between the first groove 40 and the land 12a and between the first groove 40 and the land 12b. Each of the second grooves 41 extends in the same direction as the first groove 40. That is, the second grooves 41 extend in the longitudinal direction of the lands 12a and 12b. The second grooves 41 penetrate the electronic component 20 in the spread direction of the underfill material 30 in the facing surface 13b immediately below the electronic component 20.

As shown in FIG. 1A, the underfill material 30 is disposed between the electronic component 20 and the printed substrate 10, and fixes the electronic component 20 and the printed substrate 10. The underfill material 30 spreads into the first groove 40 to be in contact with the base 11. For example, the underfill material 30 is a resin including epoxy as a main constituent. The underfill material 30 is applied to the application point P as a liquid resin. Then, the underfill material 30 spreads below the electronic component 20 by capillarity caused by a surface tension of the underfill material 30. After that, the underfill material 30 is hardened by thermal treatment and contributes to the fixation of the printed substrate 10 and the electronic component 20.

Next, effects of the printed substrate 10 and the electronic device 100 of the present embodiment will be described.

The underfill material 30 spreads from the application point P into a space between the electronic component 20 and the first main surface 13a by capillarity caused by a surface tension of the underfill material 30. Since the lands 12a and 12b and the electronic component 20 are connected through the conductive adhesive such as the solder 21, the underfill material 30 cannot be inserted from the positions where the lands 12a and 12b are formed. Therefore, the underfill material is inserted from an opening between the electronic component 20 and the first main surface 13a.

When the underfill material 30 is applied to the application point P at the center portion of the upper edge of the electronic component 20, the underfill material 30 spreads in the spread direction corresponding to a direction from top to bottom of a sheet surface of FIG. 1B. That is, the spread direction corresponds to the extension direction of the lands 12a and 12b.

Specifically, when the underfill material 30 is applied to the application point P, the underfill material 30 is inserted into the first groove 40 from the first end and spreads toward the second end of the first groove 40.

The cross-sectional view of FIG. 1A corresponds to a cross-sectional view in a surface orthogonal to the spread direction of the underfill material 30. As shown in FIG. 1A, a spreadable width (i.e., a spreadable height) of the underfill material 30 in a portion having the first groove 40 is greater than that in a portion not having the first groove 40. That is, a facing distance between the electronic component 20 and the printed substrate 10 is greater at the portion having the first groove 40 than the portion not having the first groove 40.

Generally, viscose fluid has greater spread speed as an area of a spreadable cross-section (e.g., the facing distance) is increased. In the present embodiment, the first groove 40 is provided to penetrate the substantial center between the pair of lands 12a and 12b, and the substantial center of the electronic component 20. Therefore, the spread speed of the underfill material 30 is increased at the substantial center of the electronic component 20. Additionally, since the first groove 40 of the present disclosure extends along the extension direction of the lands 12a and 12b, the underfill material 30 is likely to spread along the extension direction.

Therefore, the underfill material 30 spreads from the application point P to the bottom edge of the electronic component 20 opposite to the application point P before spreading in the arrangement direction of the lands 12a and 12b. That is, a main portion of the electronic component 20 is fixed to the printed substrate 10 before the underfill material 30 unnecessarily spreads. Accordingly, the application quantity of the underfill material 30 is limited (e.g., reduced).

The first groove 40 reaches the bottom edge of the electronic component 20 opposite to the application point P (i.e., the edge located downstream of the application point P in the spread direction). The spreading underfill material 30 exudes from the bottom edge of the electronic component 20. Accordingly, appearance check of the spreading underfill material 30 can be conducted visually or by employing a camera capable of shooting around the bottom edge of the electronic component 20.

The printed substrate 10 includes the second grooves 41. When viscose fluid spreads from a narrow space into a wide space, spread speed is decreased by a resistance provided from a pipe line. The second grooves 41 are positioned between the first groove 40 and the land 12a, and between the first groove 40 and the land 12b. Each of the second grooves 41 includes two grooves.

The underfill material 30 applied to the application point P mainly spreads along the first groove 40. Also, as described above, the underfill material 30 spreads toward the lands 12a and 12b. The spread speed of the underfill material 30 spreading toward the lands 12a and 12b is decreased by the second grooves 41 losing pressure. Therefore, the underfill material 30 is restricted from spreading toward the lands 12a and 12b across the second grooves 41.

The second grooves 41 may be omitted in the present embodiment. Even through the second grooves 41 are not formed, the underfill material 30 is restricted from spreading unnecessarily due to a difference between the spread speed of the underfill material 30 in a downward direction and the spread speed of the underfill material 30 in a horizontal direction in the sheet surface of FIG. 1B. However, when the second grooves 41 are formed, the underfill material 30 spreads in the horizontal direction of the sheet surface of FIG. 1 more slowly.

### Second Embodiment

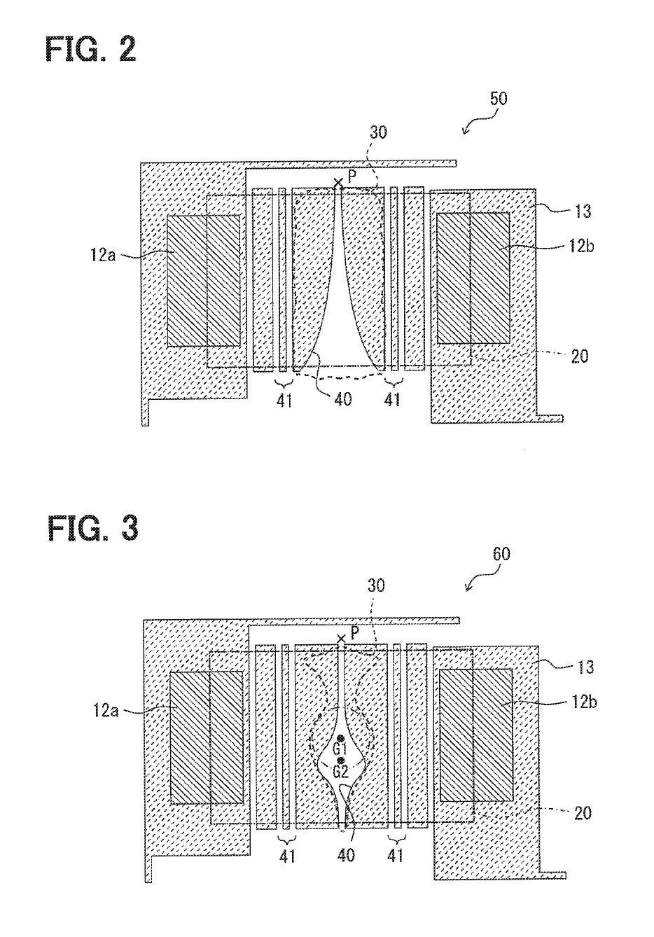

In the first embodiment, when the first groove 40 is viewed in the direction normal to the first main surface 13a, the first groove 40 has a rectangular shape. However, the shape of the first groove 40 is not limited to the rectangular shape. As shown in FIG. 2, a printed substrate 50 of the present embodiment has the first groove 40 the width of which is increased from the application point P toward the downstream side. Similarly to the first embodiment, when the substantial center of the upper edge of the electronic component 20 in the sheet surface of FIG. 2 is supposed to be the application point P, the width of the first groove 40 increases in a direction from the top toward the bottom in the sheet surface of FIG. 2. In other words, the width of the first groove 40 increases from the first end toward the second end.

The underfill material 30 applied to the application point P spreads toward the bottom of the sheet surface of FIG. 2, the quantity of the underfill material 30 spreading toward the lands 12a and 12b is decreased in the bottom of the sheet surface of FIG. 2. In other words, as close to the application point P, the underfill material 30 is likely to spread toward the lands 12a and 12b while the underfill material 30 reaches the bottom edge of the electronic component 20.

Accordingly, the width of the first groove 40 is decreased in a direction toward the application point P and is increased in a direction away from the application point P. As such, the spread underfill material 30 has a substantially rectangular shape. For example, when the underfill material 30 has the substantially rectangular shape, the underfill material 30 is gravity-symmetrically provided for the electronic component 20 having the substantially rectangular shape. Therefore, the fixation of the electronic component 20 and the printed substrate 50 is more stably achieved.

The first groove 40 of the printed substrate 50 has a shape in which an outer edge of the first groove 40 is rounded to protrude inward in the horizontal direction of the sheet surface of FIG. 2. A time taken by the underfill material 30 for spreading in the horizontal direction of the sheet surface depends on the spread speed of the underfill material 30 on the resist 13 and a distance where the resist 13 is provided. The spread speed of the underfill material 30 is determined by a material (e.g., viscosity) of the underfill material 30 and a temperature at which the underfill material 30 is applied. These are controlled in manufacturing process of the electronic device. Accordingly, the time taken by the underfill material 30 for spreading in the horizontal direction of the sheet surface depends on the distance where the resist 13 is provided.

The first groove 40 of the printed substrate 50 has the shape in which the outer edge of the first groove 40 is rounded to protrude inward so that an increasing rate of the width of the first groove 40 increases in the direction away from the application point P. Therefore, the time taken by the underfill material 30 for reaching the second grooves 41 is longer in a region far from the application point P than in a region close to the application point P. As such, the spread underfill material 30 has the substantially rectangular shape.

### Third Embodiment

The shape of the first groove 40 is suitably designed to control the range of the spread underfill material 30. For example, as shown in FIG. 3, when the first groove 40 is viewed in the direction normal to the first main surface 13a, the first groove 40 of a printed substrate 60 has a teardrop shape swelling at a part of the first groove 40 in the spread direction of the underfill material 30.

The shape of the first groove 40 is substantially line-symmetry with respect to the center line between the pair of lands 12a and 12b. An area gravity point G2 of the first groove 40 is located downstream of the area gravity point G1 of the electronic component 20 in the spread direction of the underfill material 30.

In other words, the first groove 40 has the area gravity point G2 located closer to the second end of the first groove 40 than the area gravity point G1 of the electronic component 20. Also, the first groove 40 has the area gravity point G2 shifted from the area gravity point G1 of the electronic component 20 in the extension direction of the lands 12a and 12b and toward the downstream side in the spread direction of the underfill material 30.

At an upstream side of the first groove 40 having the teardrop shape (i.e., at a part of the first groove 40 adjacent to the first end), the width of the first groove 40 is increased. Therefore, the spread of the underfill material 30 in the horizontal direction is increased toward the downstream side (i.e., toward the second end). On the other hand, at the downstream side of the first groove 40 having the teardrop shape (i.e., at a part of the first groove 40 adjacent to the second end), the width of the first groove 40 is decreased. Therefore, the spread of the underfill material 30 in the horizontal direction is decreased toward the downstream side.

As such, the underfill material 30 is provided in a substantially circular shape shown by a two-clot chain line of FIG. 3. Since the area gravity point G2 of the teardrop shape is positioned downstream of the area gravity point G1 of the electronic component 20, a portion of the first groove 40 where the width begins to increase is positioned at the area gravity point G1 of the electronic component 20. The spread of the underfill material 30 in the horizontal direction is greater at the portion where the width of the first groove 40 begins to increase than the other portion of the first groove 40. That is, when the first groove 40 has the teardrop shape and the area gravity point G2 of the first groove 40 is positioned downstream of the area gravity point G1 of the electronic component 20, the underfill material 30 is provided in the substantially circular shape having a center at the area gravity point G1 of the electronic component 20.

Actually, the underfill material 30 is expected to be provided as shown by a broken line of FIG. 3 because the underfill material 30 spreads around the point application P. Yet, when the printed substrate 60 according to the present embodiment is employed, the quantity of the underfill material 30 contributing to the fixation is increased around the area gravity point G1 of the electronic component 20.

### Other Embodiments

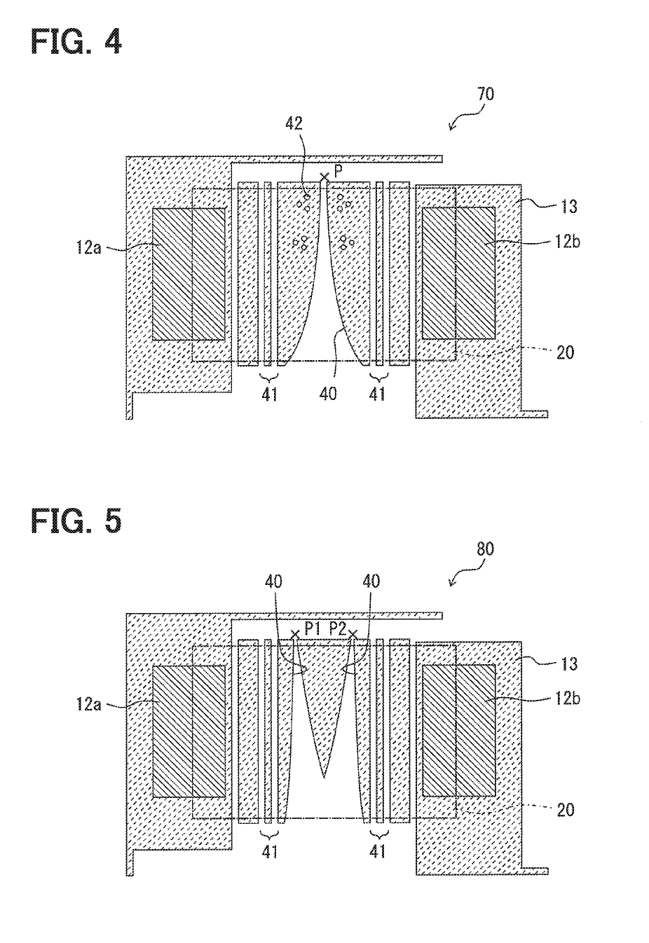

As shown in FIG. 4, a printed substrate 70 may have holes 42 in addition to the first groove 40 and the second grooves 41. The holes 42 expose the printed substrate 10. The holes 42 control the spread speed of the underfill material 30 spreading on the resist 13 toward the lands 12a and 12b. When the printed substrate 70 has the holes 42, the underfill material 30 is likely to be provided in a desired range.

In the above embodiments, the first groove 40 includes one groove. However, the number of the groove of the first groove 40 is not limited to the above embodiments. For example, as shown by a printed substrate 80 of FIG. 5, the first groove 40 may include two grooves. In FIG. 5, each of the grooves of the first groove 40 has a width increasing toward the downstream side and the grooves join with each other before reaching the bottom edge of the electronic component 20.

When a longer electronic component is mounted, the distribution of the underfill material 30 is controlled in a broader range by the first groove 40 including multiple grooves. When the first groove 40 includes multiple grooves, multiple application points may be provided corresponding to the number of the grooves. For example, as shown in FIG. 5, an application point P1 is provided for one of the first groove 40 and an application point P2 is provided for the other one of the first groove 40. Although it is preferable to apply the underfill material 30 to the application points P1 and P2 at the same time, the underfill material 30 may be applied to the application points P1 and P2 separately.

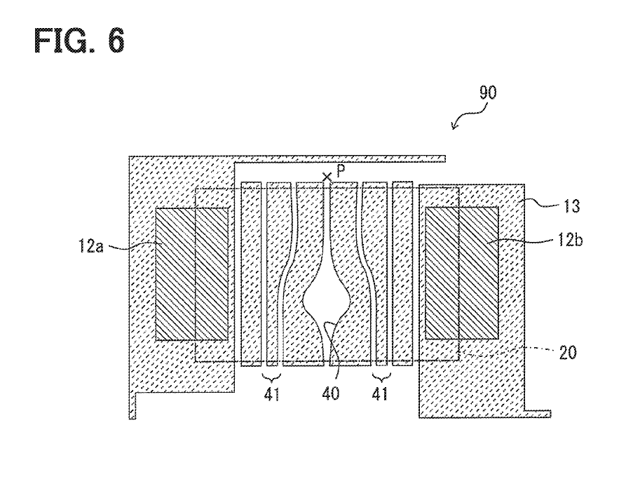

In the above embodiments, the second grooves 41 are linearly formed. However, the formation of the second grooves 41 may be arbitrarily modified as far as the direction of the formation of the second grooves 41 extends along the extension direction of the lands 12a and 12b. For example, a printed substrate 90 shown in FIG. 6 has the second grooves 41 bending correspondingly to the first groove 40 having the teardrop shape. The second grooves 41 are at least formed to divide between the first groove 40 and the lands 12a and 12b so as to function as walls decreasing the spread speed of the underfill material 30 spreading out of the first groove 40 toward the lands 12a and 12b.

In the above embodiments, the copper foil 12 and the resist 13 provide the projections at the part of the surface of the base 11 facing the electronic component 20. The projections provide the portions recessed from the first main surface 13a and exposing the base 11, and the first groove 40 and the second grooves 41 are provided by the recessed portions. However, the first groove 40 and the second grooves 41 are not necessarily provided by the projections provided by the copper foil 12 and the resist 13. For example, when the resist 13 is not formed in the surface of the base 11 facing the electronic component 20 to expose the copper foil 12, the surface of the copper foil 12 and the surface of the base 11 provide the recesses and the recesses provide the first groove 40 and the second grooves 41.

While only the selected exemplary embodiment and examples have been chosen to illustrate the present disclosure, it will be apparent to those skilled in the art from this disclosure that various changes and modifications can be made therein without departing from the scope of the disclosure as defined in the appended claims. Furthermore, the foregoing description of the exemplary embodiment and examples according to the present disclosure is provided for illustration only, and not for the purpose of limiting the disclosure as defined by the appended claims and their equivalents.

What is claimed is:

1. A printed substrate having a first surface to which an electronic component is to be fixed through an underfill material, the printed substrate comprising:
a groove that is recessed from the first surface, wherein
the first surface includes a pair of lands that is to be electrically connected to the electronic component,
the groove extends in a first direction in which the pair of lands extends, and
the groove is located in a facing region of the first surface in which the first surface is to face the electronic component.

2. The printed substrate according to claim 1, wherein
the groove has a first end and a second end facing in the first direction,
the groove has a width in a second direction orthogonal to the first direction, and
when the groove is viewed in a direction normal to the first surface, the width of the groove increases from the first end toward the second end.

3. The printed substrate according to claim 2, wherein
when the groove is viewed in the direction normal to the first surface, the groove has a shape in which an outer edge of the groove is rounded to protrude inward in the second direction.

4. The printed substrate according to claim 1, wherein
when the groove is viewed in a direction normal to the first surface, the groove has a teardrop shape swelling at a part of the groove in the first direction.

5. The printed substrate according to claim 4, wherein
the groove has a first end and a second end facing in the first direction,
the first end of the groove is to be applied with the underfill material and to allow the underfill material to spread toward the second end, and
when the groove is viewed in the direction normal to the first surface, the groove has an area gravity point located closer to the second end than an area gravity point of the electronic component.

6. The printed substrate according to claim 1, wherein
the groove has a first end and a second end facing in the first direction,
the first end of the groove is to be applied with the underfill material and to allow the underfill material to spread toward the second end, and
the groove extends so that the second end reaches a position to be located immediately below an edge of the electronic component in the first direction.

7. The printed substrate according to claim 1, wherein
the groove is referred to as a first groove,
the printed substrate further comprises a second groove that extends in the first direction, and
the second groove is located between the first groove and one of the pair of lands in the facing region of the first surface.

8. An electronic device comprising:
the printed substrate according to claim 1;
the electronic component that is fixed to the first surface; and
the underfill material that is disposed between the first surface and the electronic component.

9. The electronic device according to claim 8, wherein
when the underfill material is viewed in a direction normal to the first surface, the underfill material has a substantially rectangular shape.

10. The electronic device according to claim 8, wherein
when the underfill material is viewed in a direction normal to the first surface, the underfill material has a substantially circular shape.

11. A printed substrate having a first surface to which an electronic component is to be fixed through an underfill material, the printed substrate comprising:
a base; and
a stacked layer stacked above the base, wherein
the stacked layer provides the first surface and includes a land that is to be electrically connected to the electronic component,
the stacked layer includes a groove that is recessed from the first surface in a facing region in which the first surface is to face the electronic component, and
the groove extends in a first direction in which the land extends.
